(19) United States
(12) Patent Application Publication
(10) Pub. No.: US 2006/0219167 A1
(43) Pub. Date: Oct. 5, 2006

(54) Apparatus and method of vacuum metallic sintering for a semiconductor

(75) Inventors: Hung-Lung Cheng, Taipei City (TW); Hui-Chung Wu, Keelung City (TW); Chi-Chen Lee, Taipei City (TW)

Correspondence Address: BIRCH STEWART KOLASCH & BIRCH, PO BOX 747, FALLS CHURCH, VA, 22040-0747, US

(73) Assignee: LITE-ON SEMICONDUCTOR CORP.

(21) Appl. No.: 11/094,279

(22) Filed: Mar. 31, 2005

(51) Int. Cl. H01L 21/22

(52) U.S. Cl. 118/715

(57) ABSTRACT

An apparatus and method of vacuum metallic sintering for a semiconductor uses a quartz tube, a vacuum air-extracting apparatus, a furnace and a gas injection pipe. The metal sintered does not produce metal oxide in a vacuum established by the vacuum air-extracting apparatus. After sintering, a movable furnace can withdraw from the quartz tube immediately to decrease cooling time.

### BACKGROUND OF THE INVENTION

1. Field of the Invention

The present invention relates to an apparatus and method of vacuum metallic sintering for a semiconductor, and more particularly, to a vacuum metal sintering at a high temperature by an air-extracting apparatus and movable furnace.

2. Description of Related Art

Various metal layers are used in a semiconductor process for connecting components to each other on the wafer or to provide the contact window for backend assembly process. In a metallization process, a single layer-metal film or a multi-layer metal film is first formed on the surface of the semiconductor wafer, and a lithography and etching process is used to make the metal film to desirable pattern and size. A metal sintering process is then used to achieve the low resistance contact and high adhesive force between metal and semiconductor.

Referring to FIG. 1, a conventional apparatus of metallic sintering for a semiconductor includes a quartz tube 11 for accommodating a wafer 14, a furnace 12 mounted on the outside of the quartz tube 11 for heating the wafer 14, and a quartz boat 13 for carrying wafer 14 to the quartz tube 11. The conventional method of metallic sintering for a semiconductor includes install the quartz tube 11 into furnace 12, heat up the furnace 12 to the desirable process temperature, insert the wafer 14 to the quartz tube 11 with quartz boat 13 to start the sintering process, the conventional sintering process is working at atmosphere pressure, during the sintering process, a nitrogen gas flow is maintained to purge the quartz tube 11 from any residual oxygen and avoid production of any metal oxide on the metal layer. In fact, when the wafer 14 is placed in and removed from the quartz tube 11, the tube mouth is opened, the room air can flows back into the quartz tube 11 and cause metal oxide on the wafer 14.

### SUMMARY OF THE INVENTION

An objective of the present invention is to provide an apparatus and method of vacuum metallic sintering for a semiconductor, whereby the sintered metal does not produce metal oxide because of the vacuum air-extracting apparatus. After sintering, a movable furnace decreases cooling time for the wafer.

For reaching the objective above, the present invention provides an apparatus of vacuum metallic sintering for a semiconductor, which apparatus is described as follows. A quartz tube accommodates a wafer. A vacuum air-extracting apparatus has a vacuum piping connected to the quartz tube for evacuating air from the quartz tube; a gas injection pipe installed inside the quartz tube for transporting process gas. A furnace is movably associated with the quartz tube for heating the wafer.

The present invention provides a method of vacuum metallic sintering for a semiconductor including placing the wafer in the quartz tube, evacuating air from the quartz tube, and moving a furnace to accommodate the quartz tube and a corresponding position of the wafer. The wafer is heated and sintered in a vacuum, and a process gas is injected into the quartz tube to purge the tube from any residual oxygen and prevent production of metal oxide. After the desirable sintering time, the furnace can move out from the quartz tube and allow the wafer to cool down while the quartz tube is maintain in a vacuum. The vacuum is broken only when the wafer is going to be removed after cooling.

The movable furnace of the present invention withdraws from the quartz tube after sintering is finished to reduce the cooling time of the wafer. The wafer does not produce metal oxide due to the vacuum air-extracting apparatus. The gas injection pipe connects to the quartz tube for transporting N₂ or N₂ and H₂ mixture gas therein. When the quartz tube is purged of pure N₂ or a mixed N₂ and H₂ gas, if outside oxygen leaks into the quartz tube, and the metal is protected and does not oxidize due to N₂ dilution and H₂ reduction behavior.

Numerous additional features, benefits and details of the present invention are described in the detailed description, which follows.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a schematic view of an apparatus of metallic sintering for a semiconductor of the prior art;

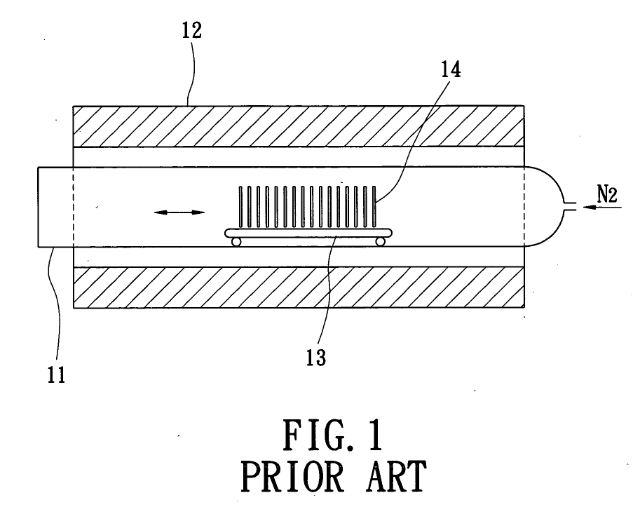

FIG. 2 is a schematic view of an apparatus of metallic sintering for a semiconductor of the present invention; and

FIG. 3 is a flowchart view of a method of metallic sintering for a semiconductor of the present invention.

### DETAILED DESCRIPTION OF PREFERRED EMBODIMENTS

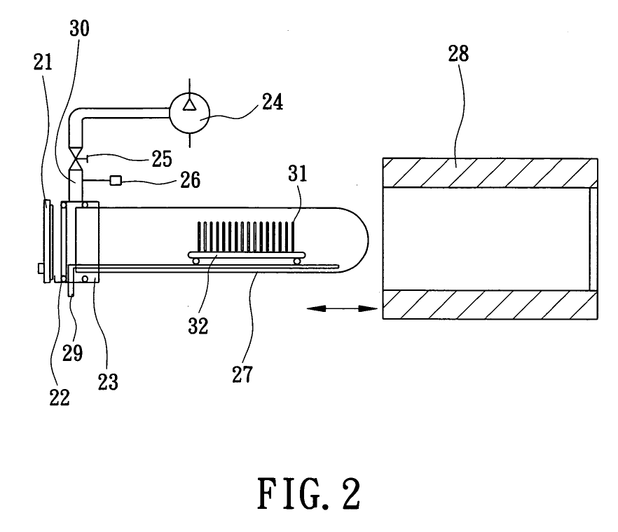

Referring to FIG. 2, an apparatus of metallic sinter for a semiconductor includes a quartz tube 27 accommodating a wafer 31, a vacuum air-extracting apparatus (includes vacuum pump 24) having a vacuum piping 30 connected to the quartz tube 27 for evacuating air from the quartz tube 27, a gas injection pipe 29 communicated with the quartz tube 27 for transporting process gas, and a furnace 28 movably associated with the quartz tube 27 for heating the wafer 31. The vacuum air-extracting apparatus (includes vacuum pump 24) further comprises a vacuum valve 25 and a vacuum sensor 26, the gas injection pipe 29 is attached to a furnace gate 23 of a furnace lid 21 for transporting process gas, and the furnace gate 23 has an O-ring 22 for vacuum seal.

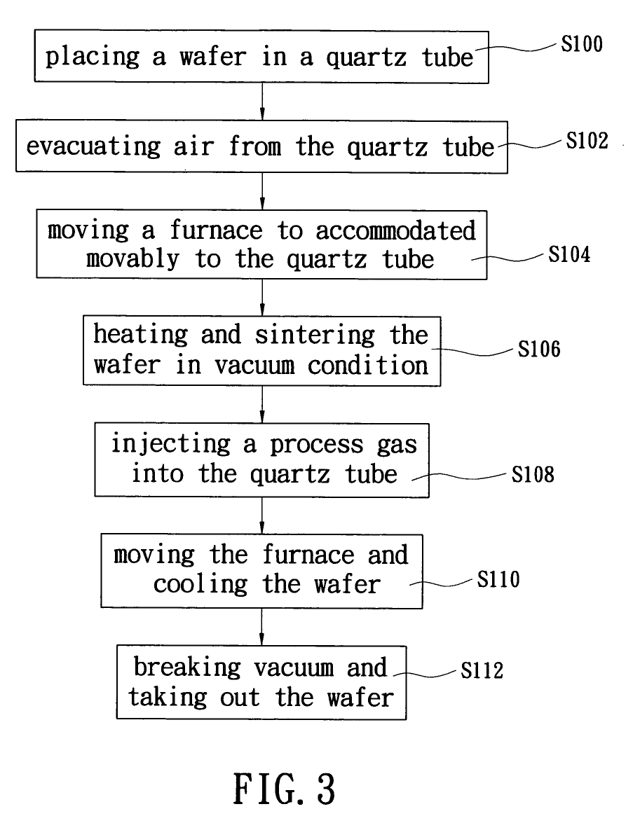

Referring to FIG. 3, a method of metallic sintering for a semiconductor includes placing a wafer 31 into a quartz tube 27 (S100), and evacuating air from the quartz tube 27 by the vacuum air-extracting apparatus (includes vacuum pump 24) (S102). A furnace 28 move to accommodates the quartz tube 27 and corresponding position of the wafer 31 (S104). The wafer 31 is heated up to the process temperature and sintered in a vacuum (S106), and a process gas is injected into the quartz tube 27 via gas injection pipe 29 to prevent production of metal oxide (S108). The furnace 28 is moved out and allow the wafer 31 to cool down to room temperature (S110) after the sintering process is finished. The vacuum is broken and the wafer 31 removed after the step of cooling the wafer 31 (S112).

The quartz tube 27 of the present invention allows air to be evacuated therefrom with the vacuum air-extracting apparatus (includes vacuum pump 24), as well as heating up and, sintering and cooling in a vacuum to avoid production of metal oxide. The movable furnace of the present invention withdraws from the quartz tube after sintering is finished to reduce cooling time of the sintered wafer.

The gas injection pipe 29 communicated with the quartz tube 27 transports N₂ or mixed N₂ and H₂ gas into quartz tube 27. When quartz tube 27 is purged of pure N₂ or mixed N₂ and H₂ gas, and outside oxygen leaks into the quartz tube, the metal does not oxidize due to N₂ dilution and H₂ reduction behavior.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are embraced within the scope of the invention as defined in the appended claims.

What is claimed is:

1. An apparatus of vacuum metallic sinter sintering for a semiconductor, comprising:
a quartz tube accommodating a wafer;
a vacuum air-extracting apparatus having a vacuum piping connected to the quartz tube for evacuating air from the quartz tube;
a gas injection pipe communicating with the quartz tube for transporting process gas; and
a furnace movably accommodating the quartz tube for heating the wafer;
wherein the wafer is sintered in a vacuum to avoid production of metal oxide.

2. A method of vacuum metallic sintering for a semiconductor, comprising:
placing a wafer in a quartz tube;
evacuating air from the quartz tube;
moving a furnace to accommodate movably the quartz tube and a corresponding position of the wafer;
heating and sintering the wafer in a vacuum; and
injecting a process gas into the quartz tube to prevent production of metal oxide.

3. The method as claimed in claim 2, further comprising moving the furnace out from the quartz tube and the wafer cool down to room temperature in a vacuum, after the step of sintering is finished.

4. The method as claimed in claim 2, further comprising breaking the vacuum and taking out the wafer after the step of cooling the wafer.
